(19) United States
(12) Patent Application Publication
(10) Pub. No.: US 2025/0311336 A1
(43) Pub. Date: Oct. 2, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Hiroyuki IRIFUNE, Ibo Hyogo (JP); Makoto MIZUKAMI, Ibo Hyogo (JP)

(21) Appl. No.: 19/235,217

(22) Filed: Jun. 11, 2025

Related U.S. Application Data
(63) Continuation of application No. PCT/JP2024/003663, filed on Feb. 5, 2024.

(30) Foreign Application Priority Data
Jul. 31, 2023 (JP) 2023-124813

(51) Int. Cl. H10D 62/10; H10D 8/50; H10D 12/00; H10D 30/63; H10D 62/832; H10D 64/62

(52) U.S. Cl. CPC H10D 62/126; H10D 8/50; H10D 12/441; H10D 30/63; H10D 62/8325; H10D 64/62; H10D 62/102; H10D 62/109

(57) ABSTRACT

A semiconductor device according to an embodiment includes a first electrode, a semiconductor layer, a second electrode, a first insulating portion, and a second insulating portion. The semiconductor layer is provided on the first electrode. The second electrode is provided on the semiconductor layer and contains aluminum. The first insulating portion includes a first portion and a second portion. The first portion is provided between the semiconductor layer and an outer peripheral portion of the second electrode. The second portion is provided around the first portion along a first plane perpendicular to a first direction, the first direction being a direction from the first electrode toward the semiconductor layer, the second portion being provided with a protruding portion on an upper surface thereof. The second insulating portion is provided on the outer peripheral portion of the second electrode and on the second portion.

### CROSS-REFERENCE TO RELATED APPLICATIONS

This is a continuation application of International Patent Application PCT/JP2024/003663, filed on Feb. 5, 2024. This application also claims priority to Japanese Patent Application No. 2023/124813, filed on Jul. 31, 2023. The entire contents of which are incorporated herein by reference.

### FIELD

Embodiments of the invention relate to a semiconductor device.

### BACKGROUND

Semiconductor devices, such as diodes, metal-oxide-semiconductor field effect transistors (MOSFETs), and insulated gate bipolar transistors (IGBTs) are used for power conversion and so on. It is desirable that semiconductor devices are not easily broken.

### BRIEF DESCRIPTION OF THE DRAWINGS

FIG. 1 is a plan view of a semiconductor device according to a first embodiment;

FIG. 2 is a cross-sectional view taken along line A1-A2 in FIG. 1;

FIG. 3 is a cross-sectional view of a semiconductor device according to a reference example;

FIGS. 4A and 4B are schematic diagrams for explaining an issue in the semiconductor device according to the reference example;

FIGS. 5A to 5D are plan views illustrating layouts of protruding portions provided on a first insulating portion;

FIG. 6 is a cross-sectional view of a part of a semiconductor device according to a first modification of the first embodiment;

FIG. 7 is a cross-sectional view of a part of a semiconductor device according to a second modification of the first embodiment;

FIG. 8 is a cross-sectional view of a part of a semiconductor device according to a third modification of the first embodiment;

FIG. 9 is a cross-sectional view of a part of a semiconductor device according to a fourth modification of the first embodiment;

FIG. 10 is a cross-sectional view of a part of a semiconductor device according to a fifth modification of the first embodiment;

FIG. 11 is a cross-sectional view of a part of a semiconductor device according to a second embodiment;

FIG. 12 is a cross-sectional view of a part of a semiconductor device according to a third embodiment; and

FIG. 13 is a cross-sectional view of a part of a semiconductor device according to a fourth embodiment.

### DETAILED DESCRIPTION

A semiconductor device according to an embodiment includes a first electrode, a semiconductor layer, a second electrode, a first insulating portion, and a second insulating portion. The semiconductor layer is provided on the first electrode. The second electrode is provided on the semiconductor layer and contains aluminum. The first insulating portion includes a first portion and a second portion. The first portion is provided between the semiconductor layer and an outer peripheral portion of the second electrode. The second portion is provided around the first portion along a first plane perpendicular to a first direction, the first direction being a direction from the first electrode toward the semiconductor layer, the second portion being provided with a protruding portion on an upper surface thereof. The second insulating portion is provided on the outer peripheral portion of the second electrode and on the second portion.

Embodiments of the invention will now be described with reference to the drawings. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated. In the drawings and the specification of the application, components similar to those described thereinabove are marked with like reference numerals, and a detailed description is omitted as appropriate.

In the following descriptions, notations of n⁺, n, n⁻ and p⁺, p represent relative heights of impurity concentrations in conductivity types. That is, n⁺ indicates an n-type impurity concentration relatively higher than n, and n⁻ indicates an n-type impurity concentration relatively lower than n. In addition, p⁺ indicates a p-type impurity concentration relatively higher than p. The embodiments described below may be implemented by reversing the p-type and the n-type of the semiconductor regions.

### First Embodiment

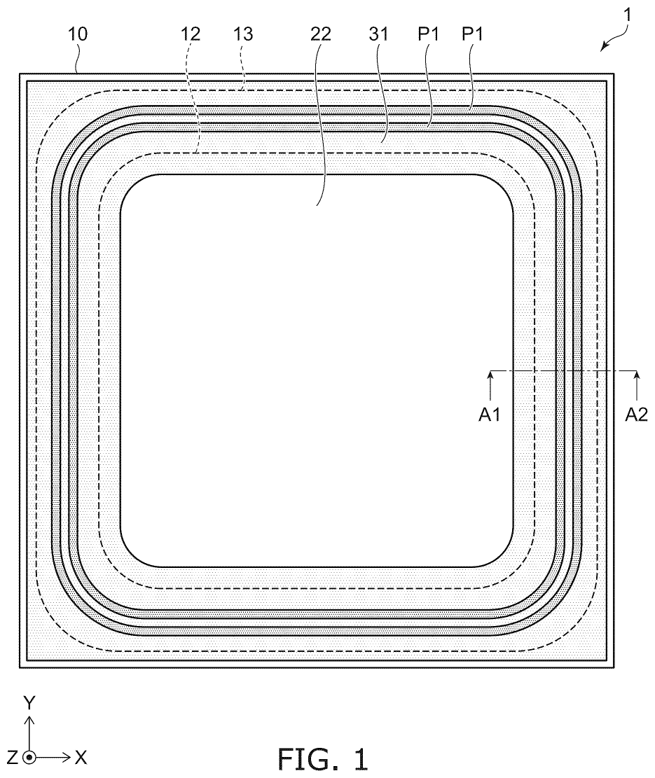

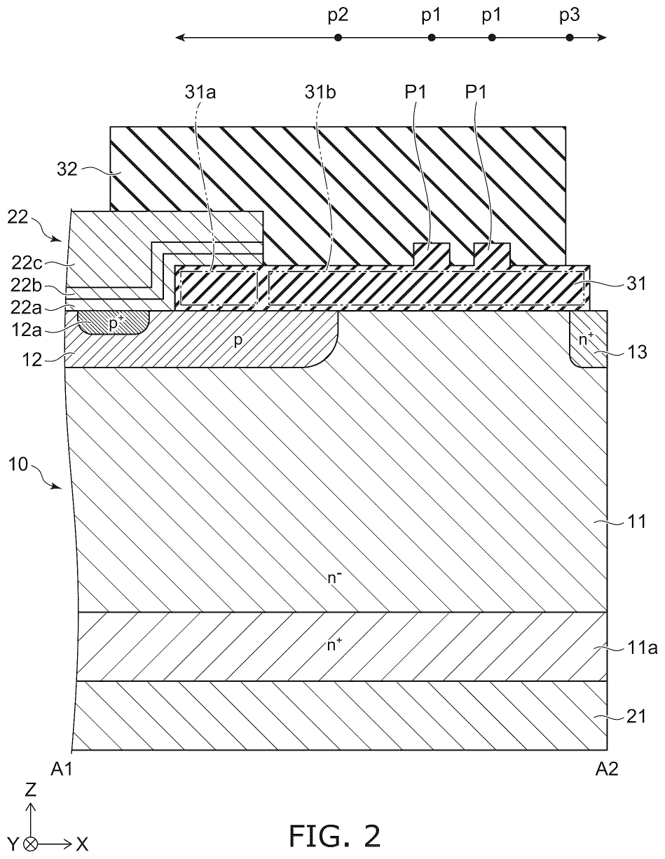

FIG. 1 is a plan view of a semiconductor device according to a first embodiment. FIG. 2 is a cross-sectional view taken along line A1-A2 in FIG. 1.

The semiconductor device according to the first embodiment is a diode. As shown in FIG. 1 and FIG. 2, a semiconductor device 1 according to the first embodiment includes a semiconductor layer 10, a lower electrode 21 (first electrode), an upper electrode 22 (second electrode), a first insulating portion 31, and a second insulating portion 32. In FIG. 1, the second insulating portion 32 is omitted.

Here, a direction from the lower electrode 21 toward the semiconductor layer 10 is taken as a Z-direction (a first direction). One direction perpendicular to the Z-direction is taken as an X-direction. A direction perpendicular to the X-direction and the Z-direction is taken as a Y-direction. In the description, the direction from the lower electrode 21 toward the semiconductor layer 10 is called “up/upward/above/higher than”, and the opposite direction is called “down/downward/below/lower than”. These directions are based on the relative positional relationship between the lower electrode 21 and the semiconductor layer 10, and are independent of the direction of gravity.

As shown in FIG. 1, the upper electrode 22 and the first insulating portion 31 are provided on the upper surface of the semiconductor device 1. The upper electrode 22 is provided in a central portion of an X-Y plane (first plane) of the semiconductor device 1, and the first insulating portion 31 is provided in an outer peripheral portion of the semiconductor device 1.

As shown in FIG. 2, the lower electrode 21 is provided on the lower surface of the semiconductor device 1. The semiconductor layer 10 is provided on the lower electrode 21. The upper electrode 22 is located on the semiconductor layer 10.

The first insulating portion 31 includes a first portion 31a and a second portion 31b. The first portion 31a is located between the semiconductor layer 10 and an outer peripheral portion of the upper electrode 22 in the Z-direction. The second portion 31b is provided around the first portion 31a along the X-Y plane. On the upper surface of the second portion 31b, a protruding portion P1 is provided.

In the example shown in FIG. 1 and FIG. 2, a plurality of protruding portions P1 are provided in a radial direction (second direction) from the first portion 31a toward the second portion 31b. The radial direction is perpendicular to the Z-direction. Each of the protruding portions P1 surrounds the upper electrode 22 along the X-Y plane.

As shown in FIG. 2, the position of at least a part of the protruding portion P1 in the Z-direction is the same as the position of at least a part of the upper electrode 22 in the Z-direction. For example, the upper surface of the protruding portion P1 is aligned with a part of the upper electrode 22 in the radial direction.

The second insulating portion 32 is provided on the outer peripheral portion of the upper electrode 22 and on the second portion 31b. The lower surface of the second insulating portion 32 is in contact with the protruding portion P1. Therefore, on the lower surface of the second insulating portion 32, one or more recessed portions corresponding to the one or more protruding portions P1 are formed.

The semiconductor layer 10 includes an n⁻-type (first conductivity type) semiconductor region 11 (first semiconductor region), an n⁺-type contact region 11a, a p-type (second conductivity type) semiconductor region 12 (second semiconductor region), a p⁺-type contact region 12a, and an n⁺-type semiconductor region 13 (third semiconductor region). In FIG. 1, the p-type semiconductor region 12 and the n⁺-type semiconductor region 13 are shown in dashed lines.

The n⁺-type contact region 11a is provided on the lower electrode 21 and is electrically connected to the lower electrode 21. The n⁻-type semiconductor region 11 is provided on the n⁺-type contact region 11a. The n-type impurity concentration of the n⁺-type contact region 11a is higher than the n-type impurity concentration of the n⁻-type semiconductor region 11.

The p-type semiconductor region 12 is provided on the n⁻-type semiconductor region 11. The p-type semiconductor region 12 is located in a central portion of the semiconductor layer 10 in the X-Y plane. The p⁺-type contact region 12a is selectively provided on the p-type semiconductor region 12. The p-type impurity concentration of the p⁺-type contact region 12a is higher than the p-type impurity concentration of the p-type semiconductor region 12.

The upper electrode 22 is located on the p-type semiconductor region 12 and on the p⁺-type contact region 12a. The p-type semiconductor region 12 and the p⁺-type contact region 12a are electrically connected to the upper electrode 22.

The n⁺-type semiconductor region 13 is provided around the p-type semiconductor region 12 along the X-Y plane. The n⁺-type semiconductor region 13 is separated from the p-type semiconductor region 12 and is located in an outer peripheral portion of the semiconductor layer 10 in the X-Y plane. The n-type impurity concentration of the n⁺-type semiconductor region 13 is higher than the n-type impurity concentration of the n⁻-type semiconductor region 11.

An example material of each component will be described.

The semiconductor layer 10 contains silicon, silicon carbide, gallium nitride, or gallium arsenide as a semiconductor material. For example, when silicon carbide is used as the semiconductor material, arsenic, phosphorus, or antimony can be used as the n-type impurity. Boron can be used as the p-type impurity.

The lower electrode 21 and the upper electrode 22 contain aluminum. Each of the lower electrode 21 and the upper electrode 22 may have a stacked structure including a plurality of metal layers. For example, as shown in FIG. 2, the upper electrode 22 includes a first metal layer 22a containing titanium, a second metal layer 22b containing titanium nitride, and a third metal layer 22c containing aluminum.

The first insulating portion 31 contains silicon oxide. The second insulating portion 32 contains an insulating resin, such as polyimide. The first insulating portion 31 is formed by, for example, chemical vapor deposition (CVD), and thereafter, a part of the first insulating portion 31 is removed by photolithography and anisotropic etching, so that the protruding portion P1 is formed.

The operation of the semiconductor device 1 will be described.

When a voltage higher than a forward voltage (VF) is applied to the upper electrode 22 with respect to the lower electrode 21, a current flows from the upper electrode 22 toward the lower electrode 21. Accordingly, the semiconductor device 1 enters the ON state. Thereafter, when the voltage applied to the upper electrode 22 falls below the forward voltage, the current decreases, and the semiconductor device 1 enters the OFF state. When a positive voltage is applied to the lower electrode 21 for the upper electrode 22, a depletion layer spreads from the p-n junction between the n⁻-type semiconductor region 11 and the p-type semiconductor region 12. At this time, the potential in the vicinity of the n⁺-type semiconductor region 13 is substantially the same as the potential of the lower electrode 21.

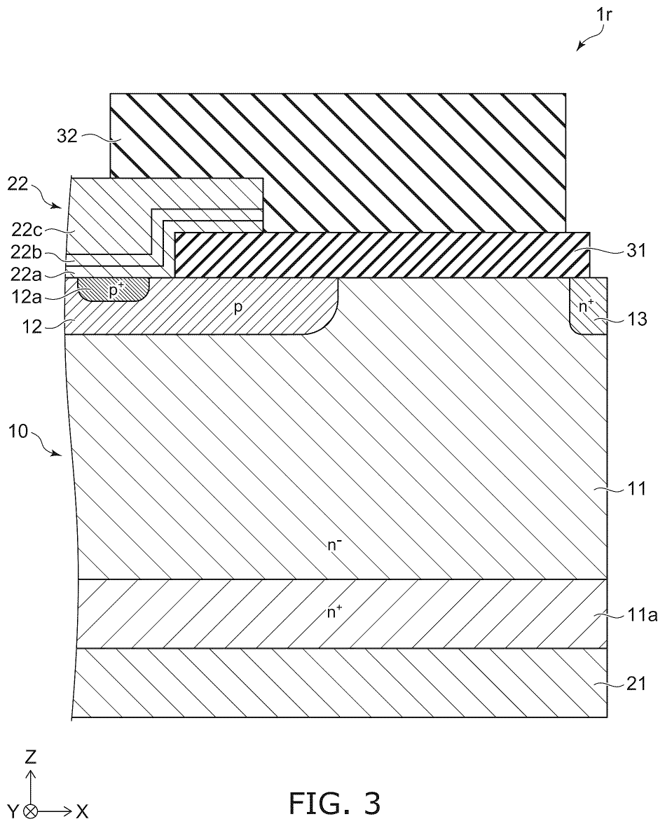

FIG. 3 is a cross-sectional view of a semiconductor device according to a reference example.

In a semiconductor device 1r shown in FIG. 3, the protruding portion P1 is not provided on the upper surface of the first insulating portion 31. The upper surface of the first insulating portion 31 is flat. In other respects, the configuration of the semiconductor device 1r is similar to that of the semiconductor device 1.

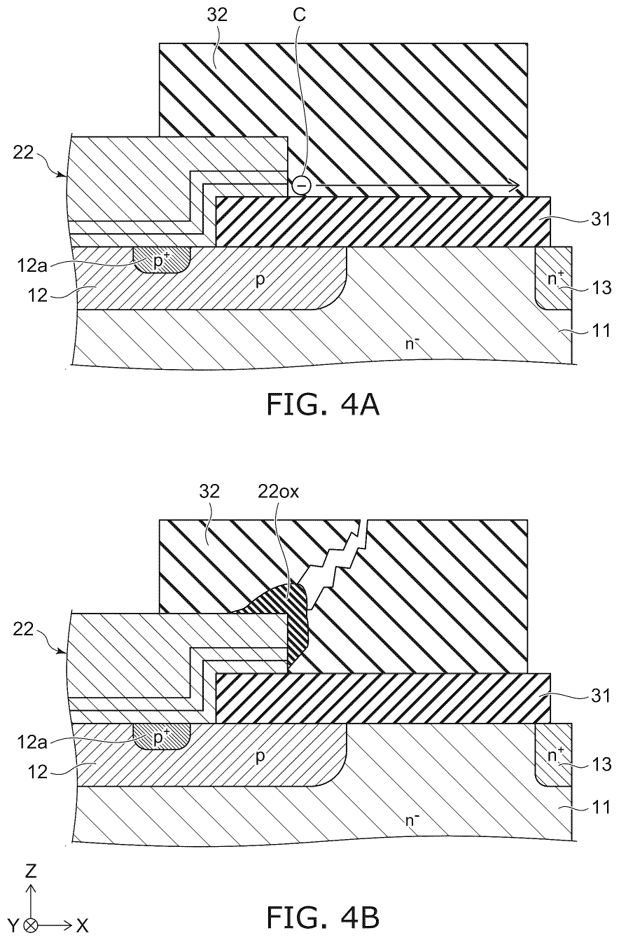

FIGS. 4A and 4B are schematic diagrams for explaining an issue in the semiconductor device according to the reference example.

The semiconductor device may be used in a high-temperature and high-humidity environment. In this case, moisture is likely to enter the second insulating portion 32.

When the entering moisture reaches the upper electrode 22, electrolysis of the moisture occurs on the surface of the upper electrode 22 as follows.

$$2 {H}_{2} O + 2 {e}^{-} \to {H}_{2} + 2 {OH}^{-}$$

The hydroxide ions make the polarity around the upper electrode 22 alkaline. Then, complex ions of aluminum are generated as follows.

$${Al ( OH )}_{3} + {OH}^{-} \to {[ {Al ( OH )}_{4} ]}^{-}$$

When the semiconductor device is in the OFF state, the potential in the vicinity of the n⁺-type semiconductor region 13 is substantially the same as the potential of the lower electrode 21. Therefore, an electric field is generated from the upper electrode 22 toward the outer peripheral portion of the semiconductor layer 10. The interface between the first insulating portion 31 and the second insulating portion 32 is contiguous with the interface between the upper electrode 22 and the first insulating portion 31 and the interface between the upper electrode 22 and the second insulating portion 32. Therefore, the complex ions C of aluminum generated at the upper electrode 22 move along the interface between the first insulating portion 31 and the second insulating portion 32 along the electric field, as shown in FIG. 4A.

Further, at the upper electrode 22, as the complex ions move, an oxide is formed as follows.

$${2 [ {Al ( OH )}_{4} ]}^{-} \to {Al}_{2} {O}_{3} + 3 {H}_{2} O + 2 {OH}^{-}$$

When the moving complex ions reach the n⁺-type semiconductor region 13, a current starts to flow between the upper electrode 22 and the n⁺-type semiconductor region 13. In response to this flow of the current, electrolysis and generation of complex ions at the upper electrode 22 are promoted. The formation of the aluminum oxide progresses, and the stress applied to the second insulating portion 32 increases. Finally, a crack appears in the second insulating portion 32 due to an oxide 22ox, as shown in FIG. 4B. Through the crack, discharge occurs between the upper electrode 22 and the outer peripheral portion of the semiconductor layer 10, and the semiconductor device 1r is broken.

In the semiconductor device 1 according to the first embodiment, the protruding portion P1 is provided on the upper surface of the first insulating portion 31. When the protruding portion P1 is provided, the movement of the complex ions of aluminum is hindered by the protruding portion P1. Since the movement of the complex ions is hindered, the flow of the current between the upper electrode 22 and the n⁺-type semiconductor region 13 can be suppressed. The electrolysis and the formation of the oxide at the upper electrode 22 are suppressed, and the possibility of a crack appearing in the second insulating portion 32 due to the oxide can be reduced. As a result, breakdown of the semiconductor device 1 due to the crack in the second insulating portion 32 is less likely to occur.

According to the first embodiment, even when the semiconductor device 1 is used in a high-temperature and high-humidity environment, the occurrence of breakdown of the semiconductor device 1 can be suppressed, and the breakdown capability of the semiconductor device 1 can be improved.

The issue described above is more likely to occur as the voltage applied to the semiconductor device is higher. The higher the applied voltage is, the more electrolysis of moisture occurs, and the oxide is more likely to be formed at the upper electrode 22. For example, in the case where the semiconductor layer 10 contains silicon carbide, the electric field strength of the dielectric breakdown of the semiconductor layer 10 can be increased as compared with the case where the semiconductor layer 10 contains single crystal silicon. Since a higher voltage can be applied to the semiconductor device, electrolysis and oxide formation at the upper electrode 22 are more likely to occur.

According to the first embodiment, even when a high voltage is applied to the semiconductor device 1, formation of the oxide at the upper electrode 22 can be suppressed. Therefore, the first embodiment of the invention is more suitable for the semiconductor device 1 in which silicon carbide is used.

As shown in FIG. 2, a position p1 of the protruding portion P1 in the radial direction is preferably between a position p2 of the p-type semiconductor region 12 and a position p3 of the n⁺-type semiconductor region 13 in the radial direction. Since the position p1 of at least any of the protruding portions P1 is between the position p2 and the position p3, the movement of the complex ions from the upper electrode 22 toward the outer peripheral portion of the semiconductor layer 10 can be effectively suppressed.

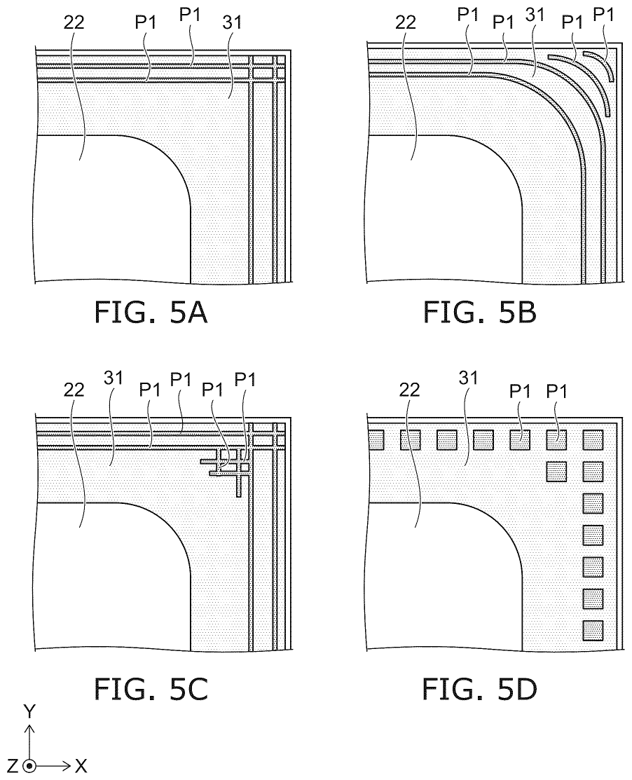

FIGS. 5A to 5D are plan views illustrating layouts of protruding portions provided on the first insulating portion.

The annular protruding portion P1 may be provided as shown in FIG. 1, or a linear protruding portion P1 may be provided as shown in FIG. 5A. In the example shown in FIG. 5A, each protruding portion P1 extends in the X-direction or the Y-direction along a side of the semiconductor device 1. The protruding portions P1 intersect each other in a corner portion of the semiconductor device 1.

As shown in FIGS. 5B and 5C, a larger number of curved protruding portions P1 or linear protruding portions P1 may be provided in a corner portion of the semiconductor device 1. Alternatively, as shown in FIG. 5D, a plurality of protruding portions P1 may be arranged along the outer periphery of the semiconductor device 1.

As shown in FIG. 1 and FIGS. 5A to 5D, any number of protruding portions P1 may be arranged as desired. When at least one protruding portion P1 is provided, the movement of the complex ions can be hindered. More preferably, the protruding portion P1 surrounds the upper electrode 22 along the X-Y plane as shown in FIG. 2 and FIGS. 5A to 5C. Accordingly, in any direction from the upper electrode 22 toward the outer peripheral portion of the semiconductor layer 10, the movement of the complex ions can be hindered by the protruding portion P1.

### First Modification

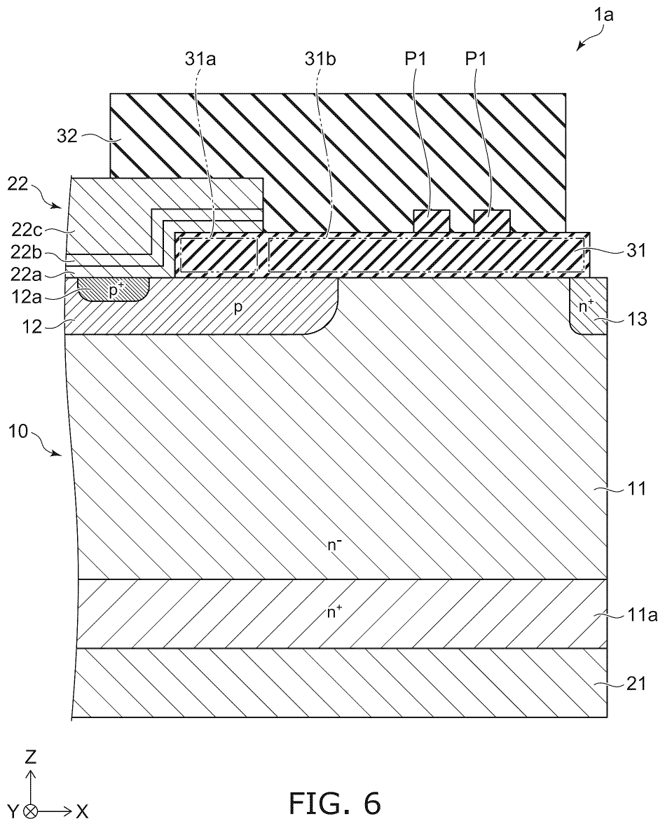

FIG. 6 is a cross-sectional view of a part of a semiconductor device according to a first modification of the first embodiment.

In a semiconductor device 1a shown in FIG. 6, the first insulating portion 31 and the protruding portion P1 are formed of separate members. For example, the first insulating portion 31 contains silicon oxide. The protruding portion P1 contains silicon oxide or silicon nitride.

As in the semiconductor device 1a, the first insulating portion 31 and the protruding portion P1 need not be an integrated member. In the semiconductor device 1a, the first insulating portion 31 and the protruding portion P1 are both made of an insulating material containing silicon. At the interface between the protruding portion P1 and the first insulating portion 31, the movement of the complex ions is more difficult than at the interface between the second insulating portion 32 containing a resin and the first insulating portion 31. Therefore, according to the first modification, the breakdown resistance of the semiconductor device 1a can be improved as compared with the semiconductor device 1r according to the reference example.

More preferably, the first insulating portion 31 and the protruding portion P1 are integrally provided. For example, the first insulating portion 31 including the protruding portion P1 is formed by processing one insulating layer. In this case, there is no interface in the region between the first insulating portion 31 and the protruding portion P1, and the first insulating portion 31 and the protruding portion P1 are seamless. Therefore, the complex ions can be prevented from passing between the first insulating portion 31 and the protruding portion P1, with more certainty. Since the first insulating portion 31 and the protruding portion P1 are integrally provided, the breakdown resistance of the semiconductor device 1 can be further improved as compared with the semiconductor device 1a.

### Second Modification

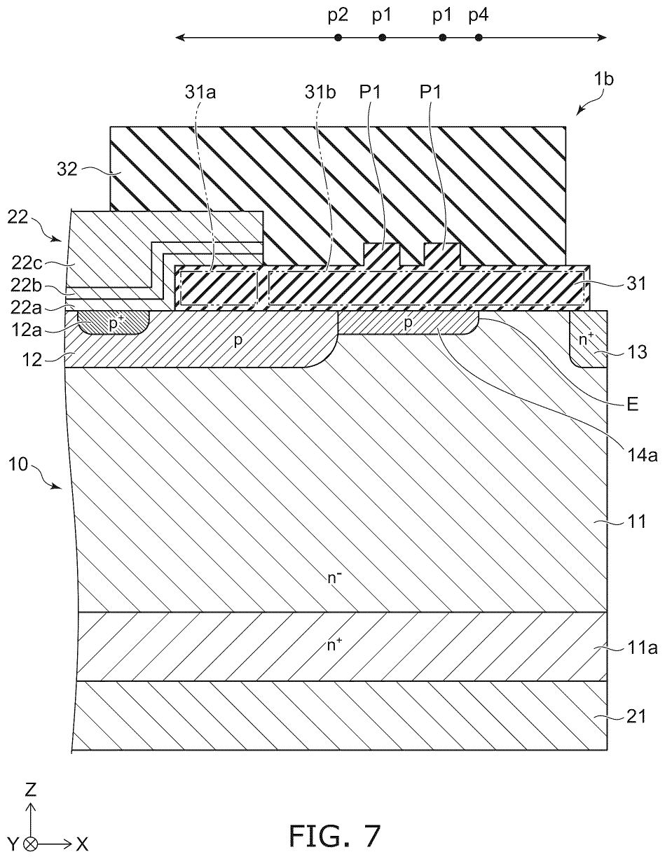

FIG. 7 is a cross-sectional view of a part of a semiconductor device according to a second modification of the first embodiment.

In a semiconductor device 1b shown in FIG. 7, as compared with the semiconductor device 1, the semiconductor layer 10 further includes a p-type RESURF region 14a (an example of a fourth semiconductor region). The p-type RESURF region 14a is provided around the p-type semiconductor region 12 along the X-Y plane.

The p-type RESURF region 14a is in contact with the p-type semiconductor region 12. The lower surface of the p-type RESURF region 14a is located above the lower surface of the p-type semiconductor region 12. The p-type impurity concentration of the p-type RESURF region 14a may be the same as the p-type impurity concentration of the p-type semiconductor region 12 or may be lower than the p-type impurity concentration of the p-type semiconductor region 12. An end portion E of the p-type RESURF region 14a in the radial direction is separated from the n⁺-type semiconductor region 13.

Since the p-type RESURF region 14a is provided, the electric field strength in an outer peripheral portion of the p-type semiconductor region 12 can be relaxed, and the withstand voltage of the semiconductor device 1b can be improved.

In the semiconductor device 1b, the position p1 of the protruding portion P1 in the radial direction is preferably between the position p2 of the p-type semiconductor region 12 in the radial direction and a position p4 of the end portion E of the p-type RESURF region 14a in the radial direction. The electric field strength is higher in the vicinity of the end portion E than in the other portion. When the complex ions move up to a region immediately above the end portion E, the complex ions are accelerated by the electric field. As a result, the complex ions reach the n⁺-type semiconductor region 13 more easily. Since the position p1 is between the position p2 and the position p4, the movement of the complex ions to the region immediately above the end portion E can be suppressed. Accordingly, the breakdown resistance of the semiconductor device 1b can be further improved.

### Third Modification

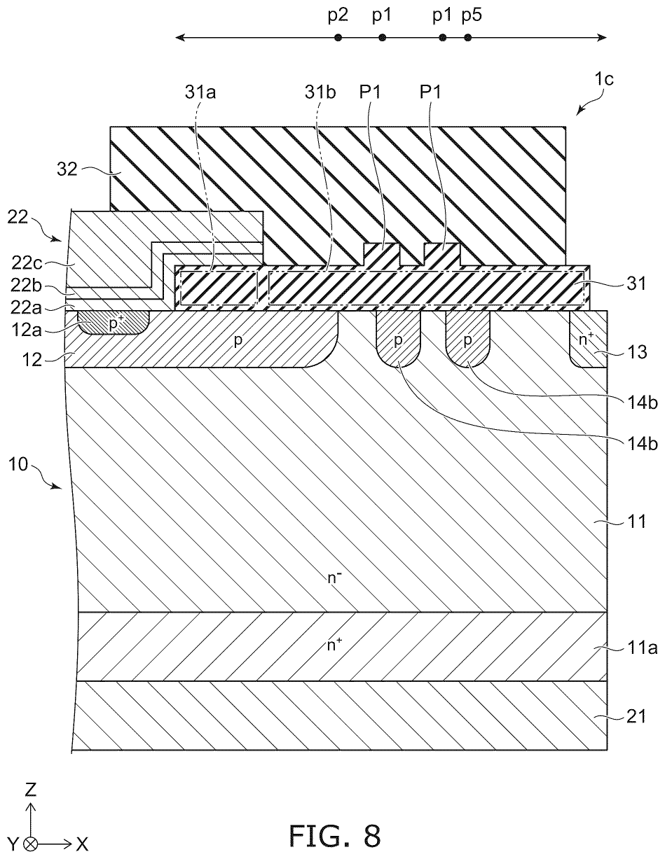

FIG. 8 is a cross-sectional view of a part of a semiconductor device according to a third modification of the first embodiment.

In a semiconductor device 1c shown in FIG. 8, as compared with the semiconductor device 1, the semiconductor layer 10 further includes a p-type guard ring region 14b (another example of the fourth semiconductor region). A plurality of p-type guard ring regions 14b, which are separated from the p-type semiconductor region 12 and the n⁺-type semiconductor region 13, are provided in the radial direction. The p-type guard ring regions 14b are separated from each other and surround the p-type semiconductor region 12 in the X-Y plane.

The thickness of the p-type guard ring region 14b in the Z-direction may be the same as the thickness of the p-type semiconductor region 12 in the Z-direction or may be smaller than the thickness of the p-type semiconductor region 12. The p-type impurity concentration of the p-type guard ring region 14b may be the same as the p-type impurity concentration of the p-type semiconductor region 12 or may be lower than the p-type impurity concentration of the p-type semiconductor region 12. The p-type guard ring regions 14b have the same p-type impurity concentration. The p-type impurity concentration of the p-type guard ring region 14b that is located closer to the outer side of the semiconductor device 1c may be lower.

In the semiconductor device 1c, the position p1 of the protruding portion P1 is preferably between the position p2 of the p-type semiconductor region 12 and a position p5 of the p-type guard ring region 14b located on the outermost periphery in the radial direction. In the vicinity of the outermost p-type guard ring region 14b, the electric field strength is higher than in the other portion. When the complex ions move up to a region immediately above the outermost p-type guard ring region 14b, the complex ions are accelerated by the electric field. As a result, the complex ions reach the n⁺-type semiconductor region 13 more easily. Since the position p1 is between the position p2 and the position p5, the movement of the complex ions to a region having a high electric field strength can be suppressed. Accordingly, the breakdown resistance of the semiconductor device 1c can be further improved.

### Fourth Modification

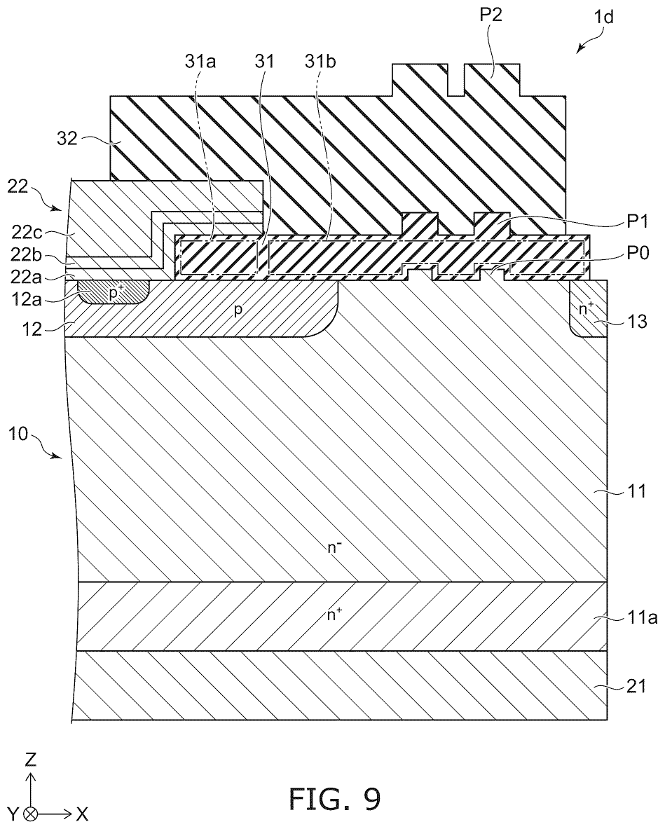

FIG. 9 is a cross-sectional view of a part of a semiconductor device according to a fourth modification of the first embodiment.

A semiconductor device 1d shown in FIG. 9 is different from the semiconductor device 1 in that a protruding portion P0 and a protruding portion P2 are provided. The protruding portion P0 is provided on the upper surface of the semiconductor layer 10. The protruding portion P2 is provided on the upper surface of the second insulating portion 32. The position of the protruding portion P0 in the X-Y plane, the position of the protruding portion P1 in the X-Y plane, and the position of the protruding portion P2 in the X-Y plane are the same.

After the semiconductor layer 10 is formed, a portion of the semiconductor layer 10 is removed so that a portion corresponding to the protruding portion P0 remains. Accordingly, the protruding portion P0 is formed on the upper surface of the semiconductor layer 10. Thereafter, the first insulating portion 31 is formed on the semiconductor layer 10, so that the protruding portion P1 is formed in accordance with the position and size of the protruding portion P0. The second insulating portion 32 is formed on the first insulating portion 31, so that the protruding portion P2 is formed in accordance with the position and size of the protruding portion P1.

The semiconductor device 1d may be molded with a resin. Since the protruding portion P2 is provided on the upper surface of the second insulating portion 32, the contact area between the second insulating portion 32 and the mold resin can be increased, and the adhesion between the second insulating portion 32 and the mold resin can be increased.

### Fifth Modification

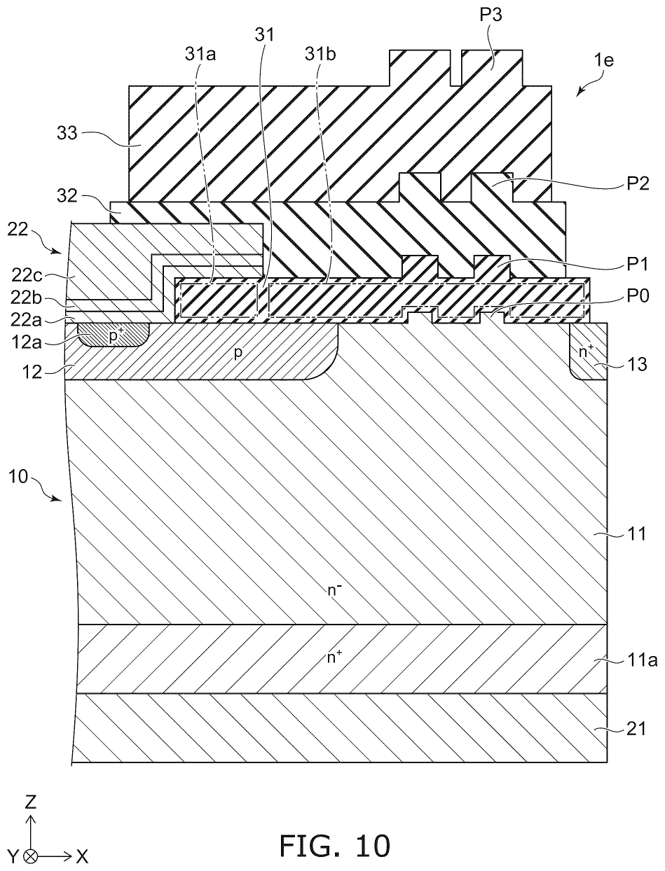

FIG. 10 is a cross-sectional view of a part of a semiconductor device according to a fifth modification of the first embodiment.

A semiconductor device 1e shown in FIG. 10 is different from the semiconductor device 1 in that the semiconductor device 1e further includes a third insulating portion 33. The third insulating portion 33 is provided on the second insulating portion 32. In the semiconductor device 1e, the second insulating portion 32 contains silicon oxide or silicon nitride. The third insulating portion 33 contains polyimide.

As in the semiconductor device 1e, an insulating portion other than the first insulating portion 31 and the second insulating portion 32 may be further provided. In the semiconductor device 1e, the protruding portion P2 may be provided on the second insulating portion 32 as in the semiconductor device 1d. In this case, a protruding portion P3 is provided on the upper surface of the third insulating portion 33. Since the protruding portion P3 is provided, when the semiconductor device 1e is molded with a resin, the adhesion between the third insulating portion 33 and the mold resin can be increased.

### Second Embodiment

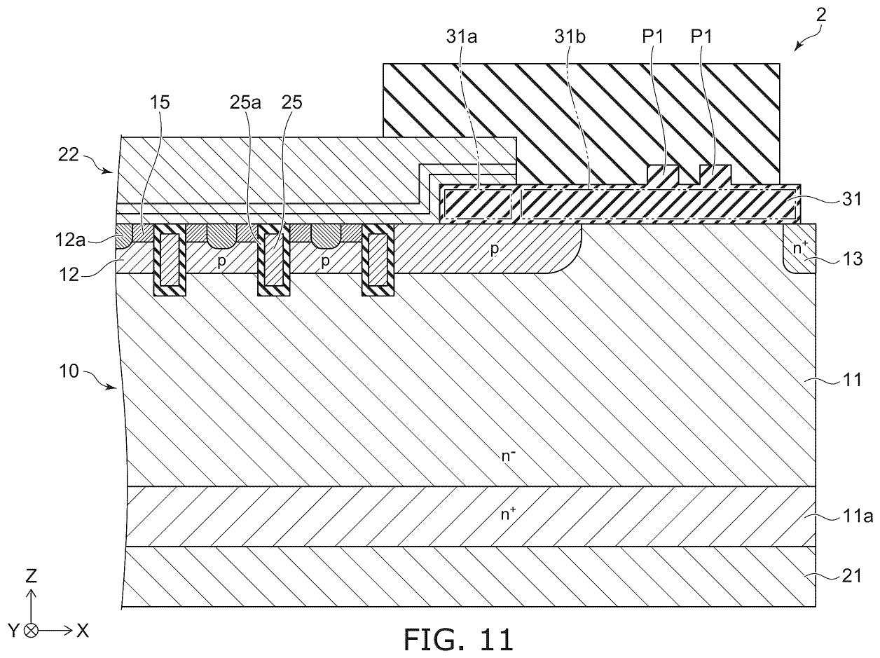

FIG. 11 is a cross-sectional view of a part of a semiconductor device according to a second embodiment.

The semiconductor device according to the second embodiment is a MOSFET. A semiconductor device 2 shown in FIG. 11 further includes a gate electrode 25 as compared with the semiconductor device 1. The semiconductor layer 10 in the semiconductor device 2 further includes an n⁺-type semiconductor region 15 (fifth semiconductor region), as compared with the semiconductor layer 10 in the semiconductor device 1.

The gate electrode 25 faces the p-type semiconductor region 12 with a gate insulating layer 25a interposed therebetween. The p⁺-type contact region 12a and the n⁺-type semiconductor region 15 are provided on the p-type semiconductor region 12. The p-type semiconductor region 12, the p⁺-type contact region 12a, and the n⁺-type semiconductor region 15 are electrically connected to the upper electrode 22.

For example, a plurality of p-type semiconductor regions 12, a plurality of p⁺-type contact regions 12a, a plurality of n⁺-type semiconductor regions 15, and a plurality of gate electrodes 25 are provided in the X-direction. Each of the p-type semiconductor regions 12, each of the p⁺-type contact regions 12a, each of the n⁺-type semiconductor regions 15, and each of the gate electrodes 25 extend in the Y-direction.

The operation of the semiconductor device 2 will be described.

In a state in which a positive voltage is applied to the lower electrode 21 for the upper electrode 22, a voltage higher than or equal to a threshold value is applied to the gate electrode 25. Accordingly, a channel (inversion layer) is formed in the p-type semiconductor region 12, and the semiconductor device 2 enters the ON state. Electrons flow from the upper electrode 22 to the lower electrode 21 through the channel. When the voltage applied to the gate electrode 25 becomes lower than the threshold value, the channel in the p-type semiconductor region 12 disappears, and the semiconductor device 2 enters the OFF state.

When the semiconductor device 2 is in the OFF state, an electric field is generated from the upper electrode 22 toward the outer peripheral portion of the semiconductor layer 10, as in the semiconductor device 1. Since the protruding portion P1 is provided on the upper surface of the first insulating portion 31, the breakdown resistance of the semiconductor device 2 can be improved as in the first embodiment.

The semiconductor device 2 shown in FIG. 11 is a trench gate MOSFET, and the gate electrode 25 faces the p-type semiconductor region 12 in the X-direction. The semiconductor device according to the second embodiment may be a planar gate MOSFET. In this case, the gate electrode 25 faces the p-type semiconductor region 12 in the Z-direction.

### Third Embodiment

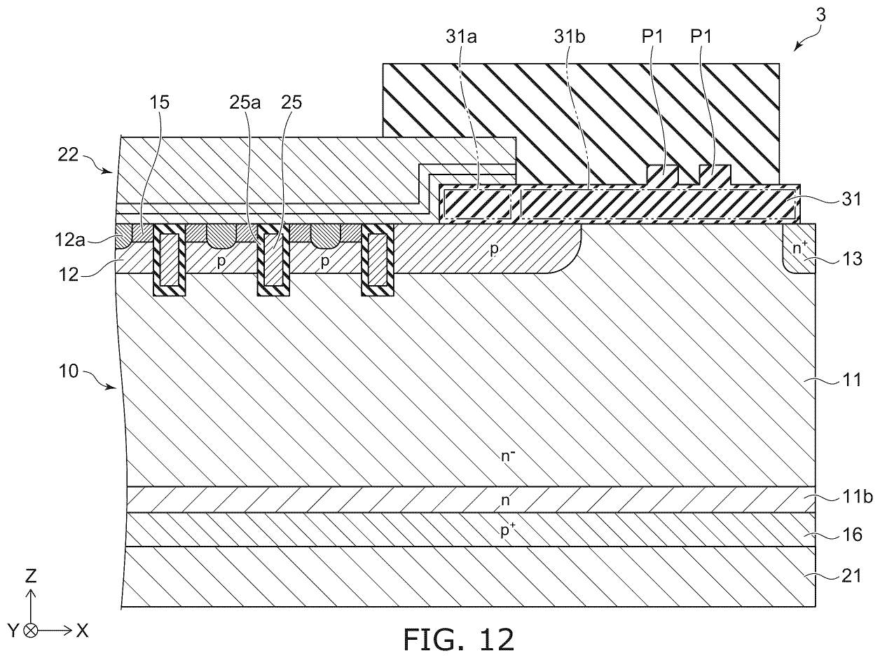

FIG. 12 is a cross-sectional view of a part of a semiconductor device according to a third embodiment.

The semiconductor device according to the third embodiment is an IGBT. In a semiconductor device 3 shown in FIG. 12, the semiconductor layer 10 includes a p⁺-type semiconductor region 16 instead of the n⁺-type contact region 11a, as compared with the semiconductor device 2. The semiconductor layer 10 further includes an n-type semiconductor region 11b.

The p⁺-type semiconductor region 16 is provided between the lower electrode 21 and the n⁻-type semiconductor region 11 and is electrically connected to the lower electrode 21. The n-type semiconductor region 11b is provided between the p⁺-type semiconductor region 16 and the n⁻-type semiconductor region 11. The n-type impurity concentration of the n-type semiconductor region 11b is higher than the n-type impurity concentration of the n⁻-type semiconductor region 11.

In a state in which a positive voltage is applied to the lower electrode 21 for the upper electrode 22, a voltage higher than or equal to a threshold value is applied to the gate electrode 25. Accordingly, a channel (inversion layer) is formed in the p-type semiconductor region 12. Electrons flow from the n⁺-type semiconductor region 15 to the n⁻-type semiconductor region 11 through the channel, and holes flow from the p⁺-type semiconductor region 16 to the n⁻-type semiconductor region 11. Conductivity modulation occurs in the n⁻-type semiconductor region 11, and the electric resistance of the semiconductor device 3 decreases to a large degree. A large current flows through the semiconductor device 3, and the semiconductor device 3 enters the ON state. Thereafter, when the voltage applied to the gate electrode 25 becomes lower than the threshold value, the channel in the p-type semiconductor region 12 disappears, and the semiconductor device 3 enters the OFF state.

When the semiconductor device 3 is in the OFF state, an electric field is generated from the upper electrode 22 toward the outer peripheral portion of the semiconductor layer 10, as in the semiconductor device 1. Since the protruding portion P1 is provided on the upper surface of the first insulating portion 31, the breakdown resistance of the semiconductor device 3 can be improved as in the first embodiment.

The structure according to each modification of the first embodiment can also be applied to the semiconductor device according to the second embodiment or the third embodiment. For example, the p-type RESURF region 14a or the p-type guard ring region 14b may be provided in the semiconductor device 2 or the semiconductor device 3. The protruding portion P0 and the protruding portion P2 may be provided in the semiconductor device 2 or the semiconductor device 3. The third insulating portion 33 may be provided in the semiconductor device 2 or the semiconductor device 3.

### Fourth Embodiment

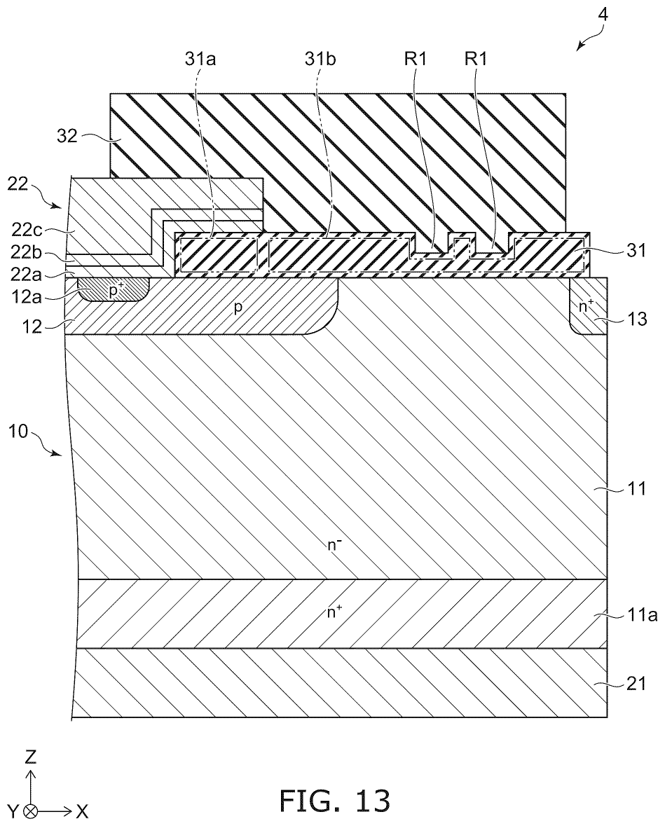

FIG. 13 is a cross-sectional view of a part of a semiconductor device according to a fourth embodiment.

In a semiconductor device 4 shown in FIG. 13, a recessed portion R1 is provided on the upper surface of the first insulating portion 31 instead of the protruding portion P1. For example, a plurality of recessed portions R1 are provided in the radial direction. Each of the recessed portions R1 surrounds the upper electrode 22 along the X-Y plane. A part of the second insulating portion 32 is located inside the recessed portion R1. Therefore, a protruding portion is provided on the lower surface of the second insulating portion 32.

Also in the case where the recessed portion R1 is provided on the upper surface of the first insulating portion 31, the movement of the complex ions from the upper electrode 22 toward the outer peripheral portion of the semiconductor layer 10 can be hindered, as in the case where the protruding portion P1 is provided. Therefore, according to the fourth embodiment, the breakdown resistance of the semiconductor device 4 can be improved as in the first embodiment.

However, in the semiconductor device 4, the thickness of a portion, of the first insulating portion 31, in which the recessed portion R1 is provided is smaller than the thickness of the other portion of the first insulating portion 31. Therefore, the electric field strength is higher in the bottom portion of the recessed portion R1 than in the other portion. When ions stay in the bottom portion of the recessed portion R1 due to the strong electric field, the spread of the depletion layer in the semiconductor layer 10 in the radial direction is affected. As a result, the withstand voltage of the semiconductor device 4 may fluctuate.

When the protruding portion P1 is provided, a partial increase in the electric field strength at the interface between the first insulating portion 31 and the second insulating portion 32 can be suppressed, and the withstand voltage of the semiconductor device can be made more stable. Therefore, when the recessed portion R1 and the protruding portion P1 are compared, it is more preferable to provide the protruding portion P1 The embodiments of the invention include the following features.

### Configuration 1

A semiconductor device including:
a first electrode;
a semiconductor layer provided on the first electrode;
a second electrode provided on the semiconductor layer and containing aluminum;
a first insulating portion including a first portion and a second portion, the first portion being provided between the semiconductor layer and an outer peripheral portion of the second electrode, the second portion being provided around the first portion along a first plane perpendicular to a first direction, the first direction being a direction from the first electrode toward the semiconductor layer, the second portion being provided with a protruding portion on an upper surface thereof; and
a second insulating portion provided on the outer peripheral portion of the second electrode and on the second portion.

### Configuration 2

The semiconductor device according to configuration 1, in which the protruding portion surrounds the second electrode along the first plane.

### Configuration 3

The semiconductor device according to configuration 2, in which the protruding portion includes a plurality of protruding portions provided in a second direction from the first portion toward the second portion.

### Configuration 4

The semiconductor device according to any one of configurations 1 to 3, in which the second portion and the protruding portion are integrally provided.

### Configuration 5

The semiconductor device according to any one of configurations 1 to 4, in which
the semiconductor layer includes
   a first semiconductor region of a first conductivity type,
   a second semiconductor region of a second conductivity type, the second semiconductor region being provided on the first semiconductor region, and
   a third semiconductor region of the first conductivity type, the third semiconductor region being provided around the second semiconductor region along the first plane, being separated from the second semiconductor region, and having a first-conductivity-type impurity concentration higher than a first-conductivity-type impurity concentration of the first semiconductor region,
the second electrode is provided on the second semiconductor region, and
a position of the protruding portion in a second direction from the first portion toward the second portion is between a position of the second semiconductor region in the second direction and a position of the third semiconductor region in the second direction.

### Configuration 6

The semiconductor device according to configuration 5, in which
the semiconductor layer further includes a fourth semiconductor region of the second conductivity type, the fourth semiconductor region being provided between the second semiconductor region and the third semiconductor region,
an end portion of the fourth semiconductor region in the second direction is separated from the third semiconductor region, and
the position of the protruding portion in the second direction is between the position of the second semiconductor region in the second direction and a position of the end portion in the second direction.

### Configuration 7

The semiconductor device according to configuration 5 or 6, further including:
a gate electrode facing the second semiconductor region with a gate insulating layer interposed therebetween, in which
the semiconductor layer further includes a fifth semiconductor region of the first conductivity type, the fifth semiconductor region being provided on the second semiconductor region.

### Configuration 8

The semiconductor device according to any one of configurations 1 to 7, in which the semiconductor layer contains silicon carbide.

In the embodiments above, the relative levels of the impurity concentrations between the semiconductor regions can be confirmed using, for example, a scanning capacitance microscope (SCM). The carrier concentration in each semiconductor region can be considered to be equal to the activated impurity concentration in each semiconductor region. Accordingly, the relative levels of the carrier concentrations between the semiconductor regions also can be confirmed using SCM. The impurity concentration in each semiconductor region can be measured, for example, using secondary ion mass spectrometry (SIMS).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A semiconductor device comprising:
a first electrode;
a semiconductor layer provided on the first electrode;
a second electrode provided on the semiconductor layer and containing aluminum;
a first insulating portion including a first portion and a second portion, the first portion being provided between the semiconductor layer and an outer peripheral portion of the second electrode, the second portion being provided around the first portion along a first plane perpendicular to a first direction, the first direction being a direction from the first electrode toward the semiconductor layer, the second portion being provided with a protruding portion on an upper surface thereof; and
a second insulating portion provided on the outer peripheral portion of the second electrode and on the second portion.

2. The semiconductor device according to claim 1, wherein the protruding portion surrounds the second electrode along the first plane.

3. The semiconductor device according to claim 2, wherein the protruding portion includes a plurality of protruding portions provided in a second direction from the first portion toward the second portion.

4. The semiconductor device according to claim 1, wherein the second portion and the protruding portion are integrally provided.

5. The semiconductor device according to claim 1, wherein
the semiconductor layer includes
a first semiconductor region of a first conductivity type,
a second semiconductor region of a second conductivity type, the second semiconductor region being provided on the first semiconductor region, and
a third semiconductor region of the first conductivity type, the third semiconductor region being provided around the second semiconductor region along the first plane, being separated from the second semiconductor region, and having a first-conductivity-type impurity concentration higher than a first-conductivity-type impurity concentration of the first semiconductor region,
the second electrode is provided on the second semiconductor region, and
a position of the protruding portion in a second direction from the first portion toward the second portion is between a position of the second semiconductor region in the second direction and a position of the third semiconductor region in the second direction.

6. The semiconductor device according to claim 5, wherein
the semiconductor layer further includes a fourth semiconductor region of the second conductivity type, the fourth semiconductor region being provided between the second semiconductor region and the third semiconductor region,
an end portion of the fourth semiconductor region in the second direction is separated from the third semiconductor region, and
the position of the protruding portion in the second direction is between the position of the second semiconductor region in the second direction and a position of the end portion in the second direction.

7. The semiconductor device according to claim 5, further comprising:
a gate electrode facing the second semiconductor region with a gate insulating layer interposed therebetween, wherein
the semiconductor layer further includes fifth semiconductor region of the first conductivity type, the fifth semiconductor region being provided on the second semiconductor region.

8. The semiconductor device according to claim 1, wherein the semiconductor layer contains silicon carbide.
